(19) United States
(12) Patent Application Publication
(10) Pub. No.: US 2025/0167088 A1
(43) Pub. Date: May 22, 2025

(54) PRINTED CIRCUIT BOARD

(71) Applicant: SAMSUNG ELECTRO-MECHANICS CO., LTD., Suwon-si (KR)

(72) Inventor: Gye Soo KIM, Suwon-si (KR)

(73) Assignee: SAMSUNG ELECTRO-MECHANICS CO., LTD., Suwon-si (KR)

(21) Appl. No.: 18/636,866

(22) Filed: Apr. 16, 2024

(30) Foreign Application Priority Data
Nov. 20, 2023 (KR) 10-2023-0161051

(51) Int. Cl. H01L 23/498; H01F 27/24; H01F 27/28; H01F 41/04; H01L 21/48

(52) U.S. Cl. CPC H01L 23/49827; H01F 27/24; H01F 27/2804; H01F 41/042; H01F 41/043; H01F 41/045; H01L 21/486; H01L 23/49866

(57) ABSTRACT

A printed circuit board includes: a substrate having a through-portion; a magnetic layer at least partially disposed in the through-portion and having a first through-hole; a first through-via layer disposed in the first through-hole; a first pattern layer disposed on an upper surface of the magnetic layer and covering at least a portion of an upper end of the first through-via layer; and a second pattern layer disposed on a lower surface of the magnetic layer and covering at least a portion of a lower end of the first through-via layer. The first through-via layer is in contact with a wall surface of the first through-hole, at least a portion of the first pattern layer is in contact with the upper surface of the magnetic layer, and at least a portion of the second pattern layer is in contact with the lower surface of the magnetic layer.

### CROSS-REFERENCE TO RELATED APPLICATION(S)

This application claims benefit of priority to Korean Patent Application No. 10-2023-0161051 filed on Nov. 20, 2023, in the Korean Intellectual Property Office, the disclosure of which is incorporated herein by reference in its entirety.

### TECHNICAL FIELD

The present disclosure relates to a printed circuit board.

Recently, in order to slim down a semiconductor chip and increase power efficiency, it is necessary to embed various passive elements such as a capacitor and an inductor in a package substrate. Meanwhile, in the case of the inductor, it is necessary to improve inductance as compared to existing chip components through material and structure changes.

### SUMMARY

An aspect of the present disclosure is to provide a printed circuit board that improve inductance.

Another aspect of the present disclosure is to a printed circuit board that may increase slimming and integration and may reduce process costs.

One of the several solutions provided through the present disclosure is to dispose a magnetic layer in a through-portion of a substrate including an inorganic insulating material such as glass, and to form a through-hole in the magnetic layer, thereby directly forming an inductor such as a magnetic composite inductor (MCI).

For example, according to an aspect of the present disclosure, a printed circuit board may include: a substrate having a through-portion; a magnetic layer at least partially disposed in the through-portion and having a first through-hole; a first through-via layer disposed in the first through-hole; a first pattern layer disposed on an upper surface of the magnetic layer and covering at least a portion of an upper end of the first through-via layer; and a second pattern layer disposed on a lower surface of the magnetic layer and covering at least a portion of a lower end of the first through-via layer. The first through-via layer may be in contact with a wall surface of the first through-hole, at least a portion of the first pattern layer may be in contact with the upper surface of the magnetic layer, and at least a portion of the second pattern layer may be in contact with the lower surface of the magnetic layer.

For example, according to another aspect of the present disclosure, a printed circuit board may include: a substrate having a through-portion; a magnetic layer at least partially disposed in the through-portion and having a through-hole; a first metal layer disposed on a wall surface of the through-hole, and extending onto an upper surface and a lower surface of the magnetic layer; and a second metal layer disposed on the first metal layer and disposed in at least a portion of the through-hole. The first metal layer may be in contact with each of the wall surface of the through-hole, the upper surface of the magnetic material layer, and the lower surface of the magnetic material layer.

For example, according to another aspect of the present disclosure, a printed circuit board may include: a substrate having a first through-portion and a second through-portion; a first magnetic layer at least partially disposed in the first through-portion and having a first through-hole; a second magnetic layer at least partially disposed in the second through-portion and having a second through-hole; a first through-via layer disposed in the first through-hole; a second through-via layer disposed in the second through-hole; a first pattern layer disposed on an upper surface of the first magnetic layer and covering at least a portion of an upper end of the first through-via layer; a second pattern layer disposed on lower surfaces of the first and second magnetic layers and covering at least a portion of each lower end of the first and second through-via layers; and a third pattern layer disposed on an upper surface of the second magnetic layer and covering at least a portion of an upper end of the second through-via layer. A portion of the substrate may be disposed between the first magnetic layer and the second magnetic layer to separate the first magnetic layer and the second magnetic layer from each other.

An effect of the present disclosure is to provide a printed circuit board that improve inductance.

Another effect of the present disclosure is to a printed circuit board that may increase slimming and integration and may reduce process costs.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example embodiment of an electronic device;

FIG. 3 is a cross-sectional view schematically illustrating an example embodiment of a printed circuit board;

FIGS. 4A to 4L are cross-sectional views schematically illustrating an example embodiment of manufacturing the printed circuit board of FIG. 3;

FIG. 5 is a cross-sectional view schematically illustrating another example embodiment of a printed circuit board;

FIGS. 6A to 6J are cross-sectional views schematically illustrating an example embodiment of manufacturing the printed circuit board of FIG. 5;

FIGS. 7A to 7F are plan views schematically illustrating various examples of a coil unit that may be applied to the printed circuit board of FIG. 3 and the printed circuit board of FIG. 5.

### DETAILED DESCRIPTION

Hereinafter, the present disclosure will be described with reference to the accompanying drawings. In the drawings, the shape and size of the elements may be exaggerated or reduced for clearer description.

### Electronic Device

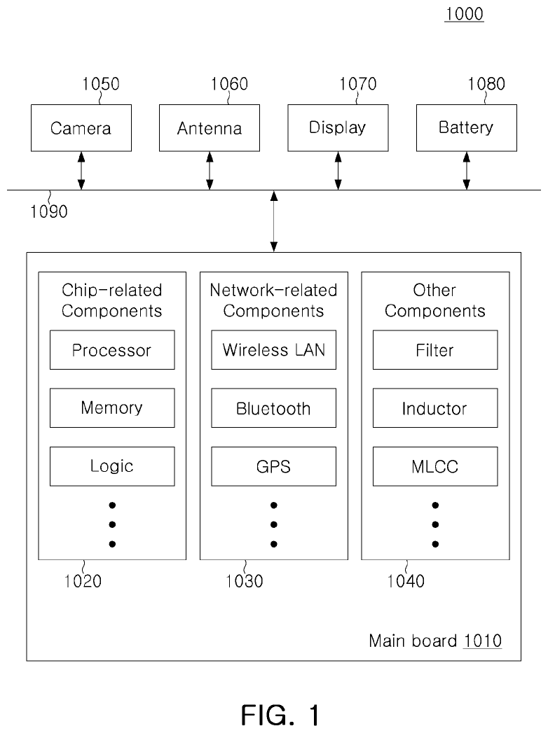

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

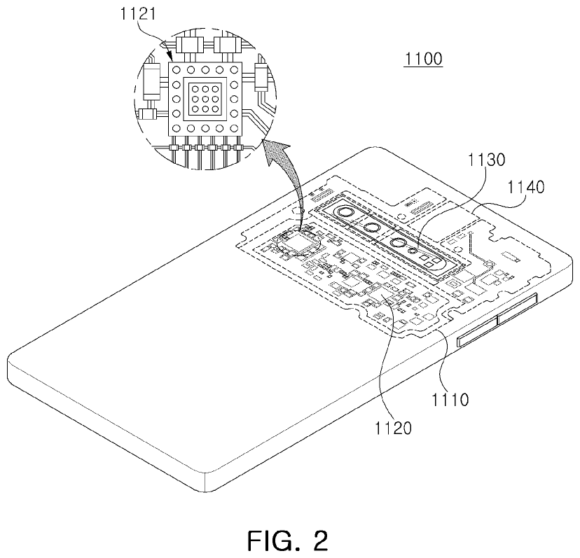

FIG. 2 is a perspective view schematically illustrating an example of an electronic device.

Referring to FIG. 2, an electronic device may be, for example, a smartphone 1100. A motherboard 1110 may be accommodated in the smartphone 1100, and various components 1120 may be physically and/or electrically connected to the motherboard 1110. Furthermore, other components that may or may not be physically and/or electrically connected to the motherboard 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may have the form of a printed circuit board in which an electronic component including an active component and/or a passive component is mounted on a surface. Alternatively, the component package 1121 may have the form of a printed circuit board in which an active component and/or a passive component are embedded. On the other hand, the electronic device is not necessarily limited to the smartphone 1100, and may be other electronic devices as described above.

### Printed Circuit Board

FIG. 3 is a cross-sectional view schematically illustrating an example embodiment of a printed circuit board.

Referring to FIG. 3, a printed circuit board 100A according to an example embodiment may include a substrate 111, a through-portion C penetrating between an upper surface and a lower surface of the substrate 111, a magnetic layer 140 at least partially disposed in the through-portion C, and a first through-via 150A including a first through-via layer 151a disposed in the first through-hole H1, a first pattern layer 152a disposed on the upper surface of the magnetic layer 140 and covering at least a portion of an upper portion of the first through-via layer 151a, and a second pattern layer 153a disposed on the lower surface of the magnetic layer 140 and covering at least a portion of a lower end of the first through-via layer 151a. In this case, the first through-via layer 151a may be in contact with a wall surface of the first through-hole H1. Additionally, at least a portion of the first pattern layer 152a may be in contact with the upper surface of the magnetic layer 140. Additionally, at least a portion of the second pattern layer 153a may be in contact with the lower surface of the magnetic layer 140. For example, the first through-via 150A may be formed directly on the magnetic layer 140.

For example, in the printed circuit board 100A according to an example embodiment, the magnetic layer 140 may be disposed in the through-portion C of the substrate 111 corresponding to a core layer, and the first through-via 150A may be directly formed in the magnetic layer 140, thus forming an inductor having a form of surrounding the magnetic layer 140. Accordingly, the electrical characteristics of the inductor may be improved. For example, the inductance of the inductor in the printed circuit board 100A may be improved. Additionally, slimming and integration of the printed circuit board 100A may be improved. Additionally, since an embedding process may be omitted, there is no need to fix the inductor with a separate insulating material, and thus, process costs may be reduced and an overall thickness may be sufficiently reduced. Meanwhile, there may be a plurality of through-portions C, the magnetic layer 140 may be disposed in each of the through-portions C, and each magnetic layer 140 may have a first through-hole H1, and thus, the above-described first through-via 150A may be formed in each of the magnetic layers 140. For example, a plurality of first through-vias 150A may be formed in the printed circuit board 100A. In this case, the plurality of first through-vias 150A may be connected to each other through the first and/or second pattern layers 152a and 153a, or may be connected to first and/or second wiring layers 121 and 122 through first and/or second via layers 131 and 132, which will be described below, thus forming one or more coil units. Accordingly, the inductance of the inductor may be improved more effectively and the electrical characteristics may be improved more effectively.

Meanwhile, the printed circuit board 100A according to an example embodiment may include a second through-hole H2 penetrating between the upper surface and the lower surface of the substrate 111, and a second through-via 160A including a second through-via layer 161a disposed in the second through-hole H2, a third pattern layer 162a disposed on the upper surface of the substrate 111 and covering at least a portion of an upper end of the second through-via layer 161a, and a fourth pattern layer 163a disposed on the lower surface of the substrate 111 and covering at least a portion of a lower end of the second through-via layer 161a. In this case, the second through-via layer 160A may be in contact with a wall surface of the second through-hole H2. Additionally, at least a portion of the third pattern layer 162a may be in contact with the upper surface of the substrate 111. Additionally, at least a portion of the fourth pattern layer 163a may be in contact with the lower surface of the substrate 111. For example, the second through-via 160A may be formed directly on the substrate 111.

For example, in the printed circuit board 100A according to an example embodiment, the second through-via 160A may be formed directly on the substrate 111 corresponding to a core layer. Through this, an electrical connection path for wiring may be formed on the substrate 111. Accordingly, the degree of freedom in designing the printed circuit board 100A may be increased. Additionally, slimming and integration of the printed circuit board 100A may be improved. Additionally, the electrical connection path may be formed simultaneously with forming the first through-via 150A, process costs may be reduced and an overall thickness may be sufficiently reduced as described above. Meanwhile, if necessary, a plurality of second through-holes H2 may be formed in the substrate 111, and, for example, a plurality of second through-vias 160A may be formed. In this case, the plurality of second through-vias 160A may be connected to each other through third and/or fourth pattern layers 162a and 163a, or may be connected to the first and/or second wiring layers 121 and 122 through first and/or second via layers 131 and 132 described below, according to the design, respectively. Accordingly, the electrical connection paths of the wiring may be formed in a more diverse manner, and the degree of design freedom may be further improved.

Meanwhile, the printed circuit board 100A according to an example embodiment may include a first insulating layer 112 disposed on an upper surface of each of the substrate 111 and the magnetic layer 140 and covering at least a portion of each of the first and third pattern layers 152a and 162a, a second insulating layer 113 disposed on a lower surface of each of the substrate 111 and the magnetic layer 140 and covering at least a portion of each of the second and fourth pattern layers 152b and 162b, a first wiring layer 121 disposed on an upper surface of the first insulating layer 112, a second wiring layer 122 disposed on a lower surface of the second insulating layer 113, a first via layer 131 penetrating through at least a portion of the first insulating layer 112 and connecting at least one of the first and third pattern layers 152a and 162a to at least a portion of the first wiring layer 121, and a second via layer 132 penetrating through at least a portion of the second insulating layer 113 and connecting at least one of the second and fourth pattern layers 153a and 163a to at least a portion of the second wiring layer 122. If necessary, the printed circuit board 100A may further include a first resist layer 171 disposed on the upper surface of the first insulating layer 112 and having a plurality of first openings o1 respectively exposing at least a portion of the first wiring layer 121, and a second resist layer 172 disposed on the lower surface of the second insulating layer 113 and having a plurality of second openings o2 respectively exposing at least a portion of the second wiring layer 122.

For example, the printed circuit board 100A according to an example embodiment may have a form of a multilayer package substrate implemented through a build-up process. Accordingly, more diverse wiring designs may be possible. Furthermore, as described above, a plurality of first through-vias 150A may be connected to the first and/or second wiring layers 121 and 122 through the first and/or second via layers 131 and 132, thus forming one or more coil units. Additionally, as described above, the first and second wiring layers 121 and 122 and the first and second via layers 131 and 132 may be connected to each other through a second through-via 160A, for example, a plurality of second through-vias 160A. Accordingly, various electrical connection paths may be provided between upper and lower components.

Meanwhile, the first through-via layer 151a may include a first-first metal layer m1 disposed on a wall surface of the first through-hole H1, a second metal layer m2 disposed on the first-first metal layer m1, and a first filling material p filling at least a portion of a space between the first-second metal layer m2. Additionally, the first pattern layer 152a may include a first-first metal layer m1 disposed on an upper surface of the magnetic layer 140, a first-second metal layer m2 disposed on the first-first metal layer m1, a first filling material p filling at least a portion of a space between the first-second metal layers m2, and a first-third metal layer m3 disposed on an upper surface of each of the first-second metal layer m2 and the first filling material p. Furthermore, the first-second pattern layer 153a may include a first-first metal layer m1 disposed on a lower surface of the magnetic layer 140, a first-second metal layer m2 disposed on the first-first metal layer m1, a first filling material p filling at least a portion of a space between the first-second metal layers m2, and a first-fourth metal layer m4 disposed on a lower surface of each of the first-second metal layer m2 and the first filling material p.

Furthermore, the second through-via layer 161a may include a second-first metal layer m1 disposed on a wall surface of the second through-hole H2, a second-second metal layer m2 disposed on the second-first metal layer m1, and a second filling material p filling at least a portion of a space between the second-second metal layers m2. Additionally, the third pattern layer 162a may include a second-first metal layer m1 disposed on an upper surface of the substrate 111, a second-second metal layer m2 disposed on the second-first metal layer m1, a second filling material p filling at least a portion of a space between the second-second metal layers m2, and a second-third metal layer m3 disposed on an upper surface of each of the second-second metal layer m2 and the second filling material p. Additionally, the fourth pattern layer 163a may include a second-first metal layer m1 disposed on a lower surface of the substrate 111, a second-second metal layer m2 disposed on the second-first metal layer m1, a second filling material p filling at least a portion of a space between the second-second metal layers m2, and a second-fourth metal layer m4 disposed on a lower surface of each of the second-second metal layer m2 and the second filling material p.

Furthermore, the second-first metal layer m1 may be substantially the same metal layer as the first-first metal layer m1. For example, each of these layers may be a first metal layer m1, and for convenience of explanation, may be divided into first-first and first-second metal layers m1. The second-second metal layer m2 may be substantially the same metal layer as the first-second metal layer m2. For example, each of these layers may be a second metal layer m2, and for convenience of explanation, may be divided into first-second and second-second metal layers m2. The second-third metal layer m3 may be substantially the same metal layer as the first-second metal layer m3. For example, each of these layers may be a third metal layer m3, and for convenience of explanation, may be divided into first-third and second-third metal layers m3. The second-fourth metal layer m4 may be substantially the same metal layer as the first-fourth metal layer m4. For example, each of these layers may be a fourth metal layer m4, and for convenience of explanation, may be divided into first-fourth metal layer and second-fourth metal layer m4. Additionally, the second filling material p may be substantially the same as the first filling material p. For example, each of these filling materials may be a filling material p, and for convenience of explanation, may be divided into first and second filling materials p.

For example, the first metal layer m1 may be a seed layer for forming the first and second through-via layers 151a and 161a and the first to fourth pattern layers 152a, 153a, 162a and 163a, and may be formed conformally and substantially uniformly with a small thickness. Meanwhile, the first metal layer m1 may be comprised of a plurality of layers and may include, for example, a titanium (Ti) layer and a copper (Cu) layer, but the present disclosure is not limited thereto. Additionally, the second metal layer m2 may be a plating layer for forming the first and second through-via layers 151a and 161a and the first to fourth pattern layers 152a, 153a, 162a and 163a, and may be formed conformally and substantially uniformly with a thickness greater than that of the first metal layer m1. Meanwhile, the second metal layer m2 may be comprised of a single layer and may include, for example, a copper (Cu) layer, but the present disclosure is not limited thereto. Additionally, the third and fourth metal layers m3 and m4 may be cap plating layers for forming the first to fourth pattern layers 152a, 153a, 162a and 163a, each of which may be formed conformally and substantially uniformly with a thickness thicker than that of the first metal layer m1. Meanwhile, each of the third and fourth metal layers m3 and m4 may be comprised of one layer and, for example, each of these layers may include a copper (Cu) layer, but the present disclosure is not limited thereto.

Additionally, a wall surface of the first through-hole H1 may be substantially perpendicular to at least one of upper and lower surfaces of the magnetic layer 140. Additionally, a wall surface of the second through-hole H2 may be substantially perpendicular to at least one of the upper and lower surfaces of the substrate 111.

For example, each of the first and second through-holes H1 and H2 may have a pillar shape whose side surface is substantially vertical on a cross-section, and may have various shapes on a plane, such as a circular shape, an oval shape, or a square shape.

Meanwhile, the magnetic layer 140 may be in contact with a wall surface of the through-portion C of the substrate 111. For example, the magnetic layer 140 may be formed by filling the through-portion C of the substrate 111 with a magnetic resin. After filling the through-portion C of the substrate 111 with the magnetic resin, a planarization process, such as a polishing process, may be performed.

For example, the upper surface and the lower surface of the magnetic layer 140 may substantially coplanar with the upper surface and the lower surface of the substrate 111, respectively. In this case, upper and lower surfaces provided by the substrate 111 and the magnetic layer 140 may be flat surfaces. Accordingly, a fine circuit pattern may be formed more easily. For example, the first to fourth pattern layers 152a, 153a, 162a and 163a may be formed at a finer pitch. Additionally, when performing a build-up process thereon, undulation, and the like, may be minimized to increase process efficiency.

Meanwhile, the substrate 111 may be an organic core layer, a glass core layer, a metal core layer, a silicon core layer, or a ceramic core layer. Preferably, the substrate 111 may be an inorganic core layer such as a glass core layer, a silicon core layer, or a ceramic core layer, and more preferably, the substrate 111 may be a glass core layer, but the present disclosure is not necessarily limited thereto.

For example, applying a glass core layer may be more advantageous in terms of costs and performance. For example, since glass itself is an insulator, there is no need for a separate insulating film, and also, since the glass is able to be produced as a panel, a process may be performed at low costs. Additionally, since the glass is a material with low transmission loss due to smoothness and insulating properties, the glass may be easily used as a material for high-frequency, high-speed signal transmission. For example, the glass may have a dielectric tangent (1 MHz) of about 0.0005 to 0.0008, which may be lower than that of an organic insulating material of 0.002 to 0.0100. Additionally, conductor loss may be caused by wiring resistance, skin effect, and surface roughness, and the skin effect is a phenomenon in which as the frequency increases when alternating current flows, a current flows only on a surface of the wiring, increasing actual resistance, which may have a very thin skin roughness of 0.7 μm at 10 GHz and 0.2 μm at 100 GHz. Furthermore, when there are irregularities on the surface of the conductor, the current flows along the irregularities, and thus, a distance through which the current flows may increase and the resistance may increase, but the glass has little surface roughness, from which loss may be low. Accordingly, when forming an inductor, such as a magnetic composite inductor (MCI), directly on this glass core layer, all of the above-described complex effects may be achieved.

Hereinafter, components of the printed circuit board 100A according to an example embodiment will be described in more detail with reference to the drawings.

The substrate 111 may be a core layer. For example, the substrate 111 may include an organic core layer, a glass core layer, a metal core layer, a silicon core layer, or a ceramic core layer. The organic core layer may include an organic insulating material. The organic insulating material may include a thermosetting resin such as an epoxy resin, a thermoplastic resin such as polyimide, or a material including an inorganic filler, an organic filler, and/or a glass fiber (Glass Fiber, Glass Cloth or Glass Fabric) along with resins. For example, the organic insulating material may be a non-photosensitive insulating material such as a Copper Clad Laminate (CCL), an Ajinomoto Build-up Film (ABF), or Prepreg (PPG), but the present disclosure is not limited thereto, and other polymer materials may be used as organic insulating materials. The glass core layer may include glass. The glass may include, for example, pure silicon dioxide (about 100% SiO₂), soda lime glass, borosilicate glass, and alumino-silicate glass. However, the present disclosure is not limited thereto, and alternative glass materials such as fluorine glass, phosphate glass, chalcogen glass, and the like, may also be used as materials for the glass layer. Additionally, other additives may be further included to form glass with specific physical properties. These additives may include calcium carbonate (e.g. lime) and sodium carbonate (e.g. soda), as well as magnesium, calcium, manganese, aluminum, lead, boron, iron, chromium, potassium, sulfur and antimony, and carbonates and/or oxides of these elements and other elements. The glass may be distinguished from the glass fiber described above. The metal core layer may include a metal. The metal may include, for example, copper (Cu), and Invar, but the present disclosure is not limited thereto. The metal core layer may include an insulating film formed on the metal. The insulating film may include an organic insulating material or an inorganic insulating material. The silicon core layer may include pure silicon (Si). If necessary, the silicon core layer may include an oxide layer formed on silicon (Si). Additionally, the silicon core layer may include a nitride layer formed on the oxide layer. The oxide layer may include a silicon oxide film, and the nitride layer may include a silicon nitride film, but the present disclosure is not limited thereto. The ceramic core layer may include a ceramic material. The ceramic material may include, for example, alumina (Al₂O₃), aluminum nitride (AlN), silicon carbide (SiC), and silicon nitride (Si₃N₄), but the present disclosure is not limited thereto.

The first and second insulating layers 112 and 113 may include an organic insulating material. The organic insulating material may include a thermosetting resin such as an epoxy resin, a thermoplastic resin such as polyimide, or a material including an inorganic filler, an organic filler, and/or a glass fiber (Glass Fiber, Glass Cloth or Glass Fabric) along with resins. For example, the organic insulating material may be a non-photosensitive insulating material such as a Copper Clad Laminate (CCL), an Ajinomoto Build-up Film (ABF), or Prepreg (PPG), but the present disclosure is not limited thereto, and other polymer materials may be used as the organic insulating materials. The first and second insulating layers 112 and 113 may include the same organic insulating material or different organic insulating materials. Each of the first and second insulating layers 112 and 113 may be comprised of multiple layers, if necessary.

Each of the first and second wiring layers 121 and 122 may include a metallic material. The metallic material may include copper (Cu), aluminum (Al), silver (Ag), tin (Sn), gold (Au), nickel (Ni), lead (Pb), titanium (Ti), and/or alloys thereof. The metallic material may include, preferably, copper (Cu), but the present disclosure is not limited thereto. Each of the first and second wiring layers 121 and 122 may perform various functions depending on the design. For example, the first and second wiring layers 121 and 122 may include a signal pattern, a power pattern, a ground pattern. Each of these patterns may have various forms such as a line, a plane, and a pad. The first and second wiring layers 121 and 122 may include a seed layer and a plating layer formed on the seed layer. The seed layer may be an electroless plating layer (or chemical copper) and/or a sputtering layer, and the plating layer may be an electrolytic plating layer (or electrolytic copper), but the present disclosure is not limited thereto.

Each of the first and second via layers 131 and 132 may include a metallic material. As described above, the metallic material may include copper (Cu), aluminum (Al), silver (Ag), tin (Sn), gold (Au), nickel (Ni), lead (Pb), titanium (Ti), and/or alloys thereof. The metallic metal may include, preferably, copper (Cu), but the present disclosure is not limited thereto. Each of the first and second via layers 131 and 132 may include a filled via filling a via hole, but may include a conformal via disposed along a wall surface of the via hole. The first and second via layers 131 and 132 may perform various functions depending on the design. For example, the first and second via layers 131 and 132 may include a ground via, a power via, a signal via. Each of the first and second via layers 131 and 132 may include first and second connection vias tapered in opposite directions. Each of the first and second via layers 131 and 132 may include an electroless plating layer (or chemical copper) and an electrolytic plating layer (or electrolytic copper). The first and second via layers 131 and 132 may include a sputtering layer instead of an electroless plating layer (or chemical copper), or may include both the sputtering layer and the electroless plating layer (or chemical copper).

The magnetic layer 140 may include a magnetic material. The magnetic material may include, for example, a ferrite-based material, and a permalloy-based material. For example, the magnetic material may include a Ni-based ferrite, a Ni—Zn— based ferrite, a Ni—Zn—Cu-based ferrite, a Fe—Si—Al (Sendust), a Ni—Mo—Fe (MPP: Molypermalloy Powder Core), and a Ni—Fe (High Flux Core), but the present disclosure is not limited thereto, and the magnetic material may also include other known ferrite-based materials or permalloy-based materials. Additionally, various types of magnetic materials including other magnetic powder particles and/or magnetic particles may be used as the magnetic materials. This magnetic material may fill the through-portion C in the form of a paste or a composition, and may then be hardened to form a magnetic material layer 140. Accordingly, the magnetic layer 140 may be in contact the wall surface of the through-portion C. For example, the magnetic layer 140 may be in contact with the substrate 111.

The first through-via 150A may include a first through-via layer 151a and first and second pattern layers 152a and 153a. As described above, the first through-via layer 151a may include the first and second metal layers m1 and m2 and a filling material p. The first and second pattern layers 152a and 153a may include the first to fourth metal layers m1, m2, m3 and m4 and the filling material p as described above. The first metal layer m1 may include a first layer formed by sputtering and a second layer formed by electroless plating, and the first layer may include a titanium (Ti) layer and a copper (Cu) layer, and the second layer may include a copper (Cu) layer, but the present disclosure is not limited thereto. Each of the second to fourth metal layers m2, m3 and m4 may be formed by electrolytic plating, each of which may include a copper (Cu) layer, but the present disclosure is not limited thereto. The filling material p may include a plugging material. The plugging material may include an insulating ink including an insulating resin such as epoxy. However, the present disclosure is not limited thereto and the plugging material may include conductive ink. The first pattern layer 152a and/or the second pattern layer 153a may extend onto the substrate 111. For example, the first pattern layer 152a and/or the second pattern layer 153a of each of the plurality of first through-vias 150A may be connected to each other. The first and second pattern layers 152a and 153a may include a line pattern and a pad pattern, but the present disclosure is not limited thereto. Meanwhile, only the pad may include the filling material p, and the line may not include the filling material p.

The second through-via 160A may include a second through-via layer 161a and third and fourth pattern layers 162a and 163a. As described above, the second through-via layer 161a may include the first and second metal layers m1 and m2 and a filling material p. The third and fourth pattern layers 162a and 163a may include the first to fourth metal layers m1, m2, m3 and m4 and the filling material p as described above. The first to fourth metal layers m1, m2, m3 and m4 and the filling material p may be substantially the same as those described for the first through-via 150A. Each of the third and fourth pattern layers 162a and 163a may perform various functions depending on the design. For example, the third and fourth pattern layers 162a and 163a may include a signal pattern, a power pattern, and a ground pattern. Each of these patterns may have various forms such as a line, a plane, and a pad. Meanwhile, only the pad may include the filling material p, and the line and the plane may not include the filling material p.

The first and second resist layers 171 and 172 may include a liquid or film-type solder resist, but is not limited thereto, and may also include other organic insulating materials such as an Ajinomoto Build-up Film (ABF) or the like. Each of the first and second resist layers 171 and 172 may have first and second openings o1 and o2. The first and second openings o1 and o2 may be provided in plural form. Each of the first and second openings o1 and o2 may be formed of Solder Mask Defined (SMD) and/or Non Solder Mask Defined (NSMD). The first and second openings o1 and o2 may expose at least a portion of the first and second wiring layers 121 and 122, respectively, and a surface treatment layer may be disposed on a surface of the exposed pattern. The surface treatment layer may be formed by electrolytic gold plating, electroless gold plating, Organic Solderability Preservative (OSP) or electroless tin plating, electroless silver plating, electroless nickel plating/substituted gold plating, Direct Immersion Gold (DIG) plating, or Hot Air Solder Leveling (HASL).

If necessary, a semiconductor chip may be disposed on the first resist layer 171. The semiconductor chip may be electrically connected to the first through-via 150A. The semiconductor chip may be, for example, an integrated circuit (IC) die in which several hundreds to several millions of elements are integrated into one chip. The integrated circuit die may be formed based on an active wafer, in which case silicon (Si), germanium (Ge), gallium arsenide (GaAs), and the like, may be used as a base material forming each body. Various circuits may be formed in the body. A connection pad may be formed on a front surface of the body for a connection to an external circuit, such as a signal, electricity, ground, or the like, and the connection pad may include a conductive material such as aluminum (Al) or copper (Cu).

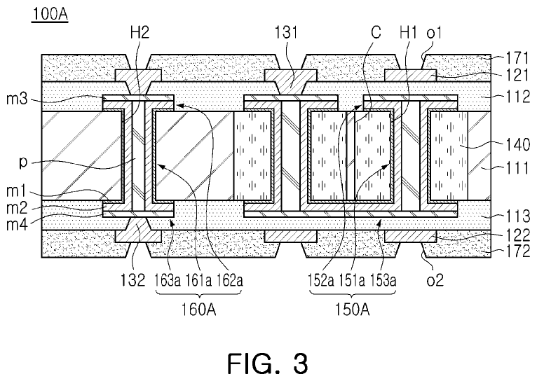

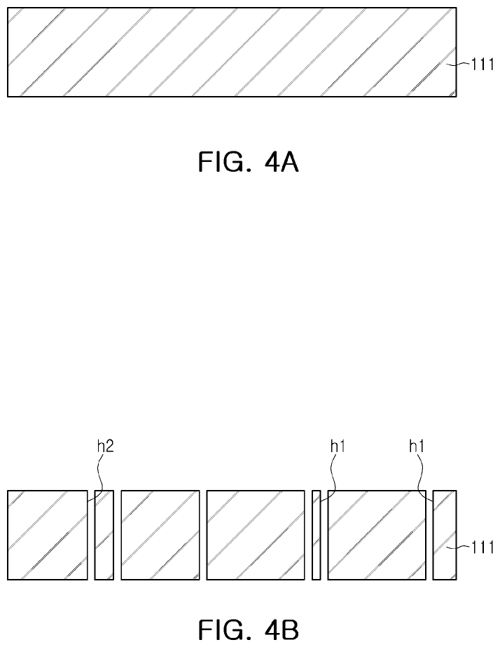

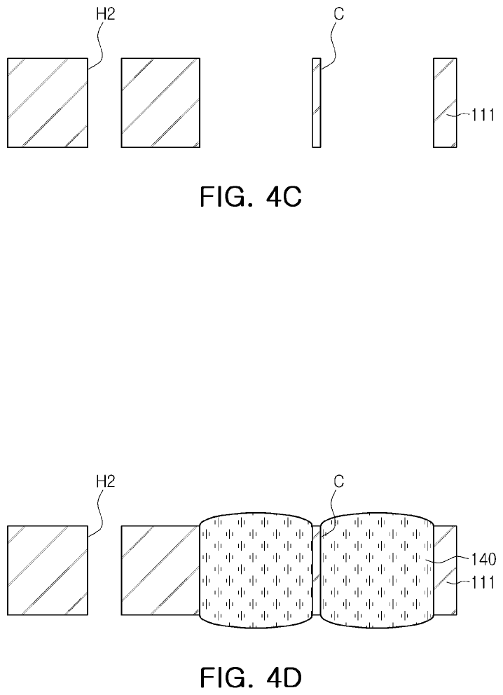

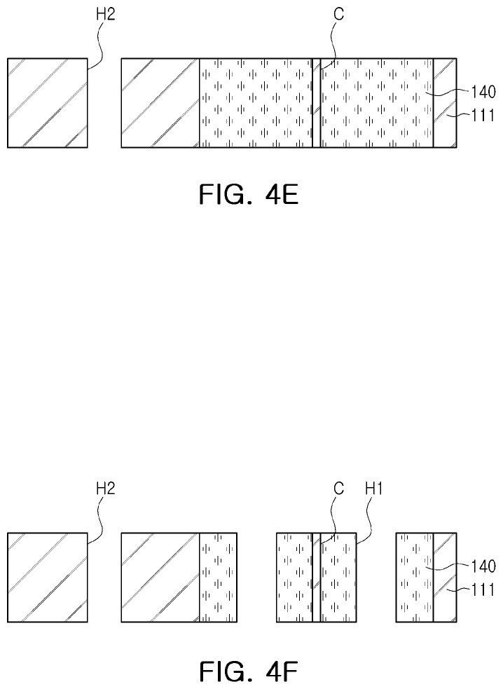

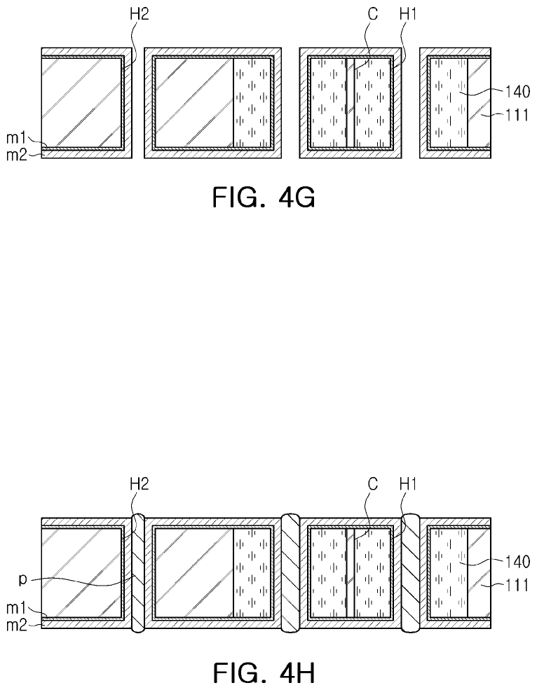

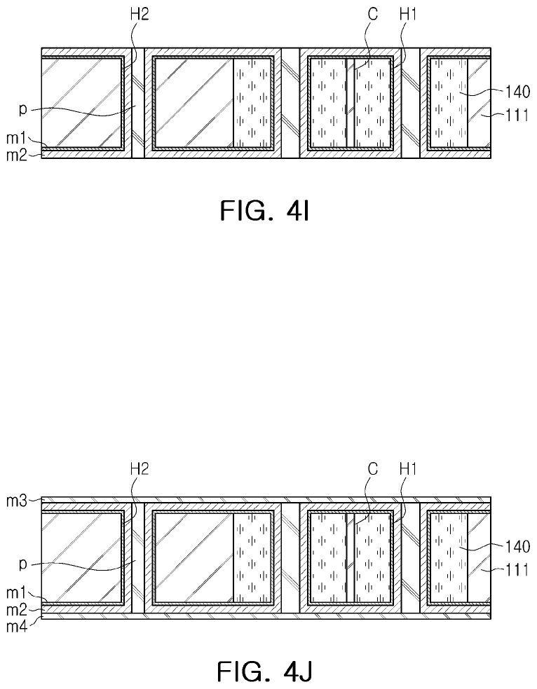

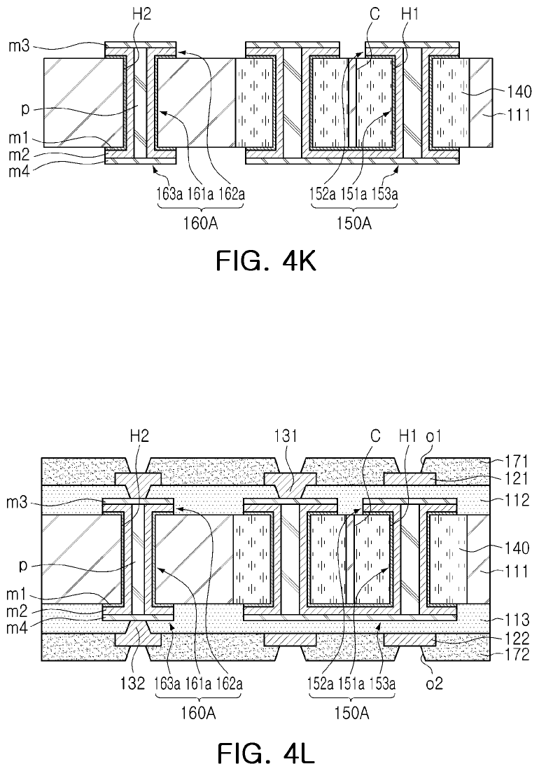

FIGS. 4A to 4L are cross-sectional views schematically illustrating an example embodiment of manufacturing the printed circuit board of FIG. 3.

Referring to FIG. 4A, a substrate 111 may be prepared. The substrate 111 may include an organic core layer, a glass core layer, a metal core layer, a silicon core layer, or a ceramic core layer, and may include, more preferably, a glass core layer. When the substrate 111 includes the glass core layer, a glass plate or the like may be prepared.

Referring to FIG. 4B, a plurality of holes h1 and h2 may be formed in the substrate 111. The plurality of holes h1 and h2 may be used when forming a through-portion C or a second through-hole H2, which will be described below. The plurality of holes h1 and h2 may be formed through laser processing or the like.

Referring to FIG. 4C, a through-portion C and a second through-hole H2 may be formed in the substrate 111. The through-portion C and the second through-hole H2 may be formed by expanding a plurality of holes h1 and h2 previously formed in the substrate 111. For example, the plurality of holes h1 and h2 may be expanded through chemical etching to form the through-portion C and the second through-hole H2. If necessary, a plurality of through-portions C may be formed.

Referring to FIG. 4D, a magnetic layer 140 may be formed in the through-portion C. For example, the magnetic material layer 140 may be formed by filling the through-portion C using a magnetic paste or a magnetic composition and hardening the through-portion C. When there are a plurality of through-portions C, the magnetic layers 140 may be formed in each of the through-portions C.

Referring to FIG. 4E, the magnetic layer 140 may be flattened. For example, a polishing process may be performed so that an upper surface and a lower surface of the magnetic layer 140 are substantially coplanar with an upper surface and a lower surface of the substrate 111, respectively. When there are a plurality of magnetic layers 140, the polishing process may be flattened in substantially the same manner.

Referring to FIG. 4F, a first through-hole H1 may be formed in the magnetic layer 140. The first through-hole H1 may be formed using a mechanical drill or the like. When there are a plurality of magnetic layers 140, a first through-hole H1 may be formed in each of the magnetic layers 140.

Referring to FIG. 4G, first and second metal layers m1 and m2 may be formed on the substrate 111, the magnetic layer 140, and the first and second through-holes H1 and H2. For example, the first metal layer m1 may be formed by performing sputtering using titanium (Ti), copper (Cu), or the like, as a material. If necessary, electroless plating may be performed after sputtering. For example, the first metal layer m1 may also include chemical copper. Next, electroplating may be performed using a material such as copper (Cu), thus forming the second metal layer m2. The first and second metal layers m1 and m2 may be formed conformally. The second metal layer m2 may be formed to be thicker than the first metal layer m1.

Referring to FIG. 4H, a space between the second metal layers m2 in the first and second through-holes H1 and H2 may be filled with a filling material p. The filling material p may protrude beyond an upper surface and a lower surface of the second metal layer m2. The filling material p may be formed in a plugging process.

Referring to FIG. 4I, the filling material p may be flattened. For example, a polishing process may be performed so that each of an upper surface and a lower surface of the filling material p may be substantially coplanar with each of an upper surface and a lower surface of the second metal layer m2.

Referring to FIG. 4J, third and fourth metal layers m3 and m4 covering the second metal layer m2 and the filling material p may be formed on an upper side and a lower side of the second metal layer m2 and the filling material p, respectively. Each of the third and fourth metal layers m3 and m4 may be formed by electroplating using copper (Cu), or the like, as a material.

Referring to FIG. 4K, first and second through-vias 150A and 160A may be formed. For example, the first to fourth metal layers m1, m2, m3 and m4 may be patterned through chemical etching to form the first to fourth pattern layers 152a, 153a, 162a and 163a. Accordingly, the first and second through-vias 150A and 160A described above may be formed.

Referring to FIG. 4L, through a build-up process, and the like, the first and second insulating layers 112 and 113, the first and second wiring layers 121 and 122, and the first and second via layers 131 and 132 may be formed as many layers as the required number of layers. Additionally, first and second resist layers 171 and 172 may be formed. Additionally, a plurality of first and second openings o1 and o2 may be formed in the first and second resist layers 171 and 172, respectively. Meanwhile, the first and second insulating layers 112 and 113 may be formed in a lamination process, and the like, and the first and second wiring layers 121 and 122 and the first and second via layers 131 and 132 may be formed in a plating process after via hole processing, and the first and second resist layers 171 and 172 may be formed in a lamination process or a coating process of a liquid material. Additionally, the plurality of first and second openings o1 and o2 may be formed in a photolithography process or a laser drill, depending on the material of the first and second resist layers 171 and 172.

The printed circuit board 100A according to the above-described example embodiment may be manufactured through a series of processes, and other descriptions may be substantially the same as those described for the printed circuit board 100A according to the above-described example embodiment, and thus, overlapping descriptions thereof will be omitted.

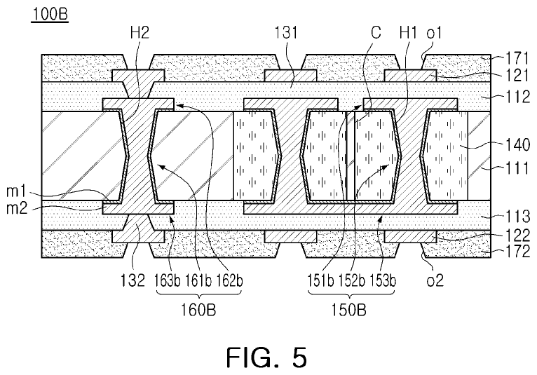

FIG. 5 is a cross-sectional view schematically illustrating another example embodiment of a printed circuit board.

Referring to FIG. 5, in a printed circuit board 100B according to another example embodiment, first and second through-holes H1 and H2 and first and second through-vias 150B and 160B formed therein may have different shapes, as compared to the printed circuit board 100A according to the above-described example embodiment. For example, wall surfaces of each of the first and second through-holes H1 and H2 may have a plurality of inclined surfaces inclined with respect to an upper surface and/or a lower surface of the magnetic layer 140 and the substrate 111, respectively. For example, each of the first and second through-holes H1 and H2 may have an hourglass shape on a cross-section, but the shape is not limited thereto. Additionally, the first and second through-via layers 151b and 161b of the first and second through-vias 150B and 160B may include a first metal layer m1 disposed on wall surfaces of the first and second through-holes H1 and H2, respectively, and a second metal layer m2 disposed on the first metal layer m1 and filling at least a portion of each of the first and second through-holes H1 and H2 without a filling material. In this case, the first metal layer m1 may be divided into first-first and first-second metal layers m1 as described above, for convenience of explanation, and the second metal layer m2 may be divided into first-second and second-second metal layers m2 as described above, for convenience of explanation. Additionally, the first and second pattern layers 152b and 153b of the first through-via 150B may include a first metal layer m1 disposed on an upper surface and a lower surface of the magnetic layer 140, respectively, and a second metal layer m2 disposed on the first metal layer m1, and separate cap plating may be omitted on the second metal layer m2. Additionally, the third and fourth pattern layers 162b and 163b of the second through-via 160B may include a first metal layer m1 disposed on an upper surface and a lower surface of the substrate 111, respectively, and a second metal layer m2 disposed on the first metal layer m1, and separate cap plating may be omitted on the second metal layer m2.

For example, in the case of the printed circuit board 100B according to another example embodiment, the plating time may be longer than the printed circuit board 100A according to an example embodiment, but thicknesses of the first to fourth pattern layers 152b, 153b, 162b and 163b may be reduced, which may be more advantageous in forming microcircuits. Additionally, since a thickness of the second metal layer m2 in the first and second through-via layers 151b and 161b becomes thicker, a function such as an inductor may be further improved.

Other descriptions may be substantially the same as those described for the printed circuit board 100A according to the above-described example embodiment, and thus overlapping descriptions thereof will be omitted.

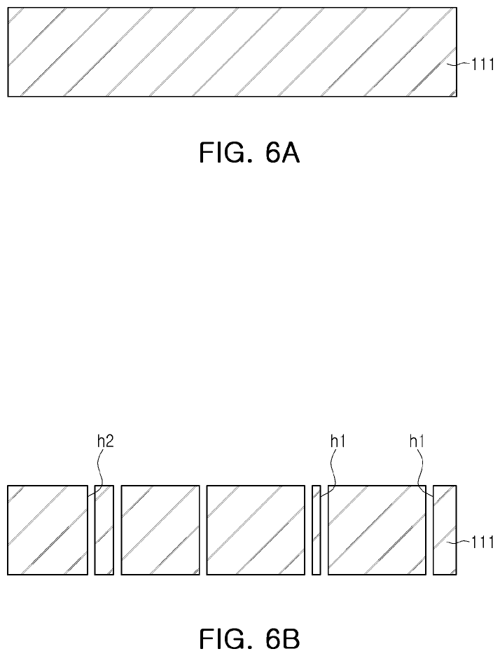

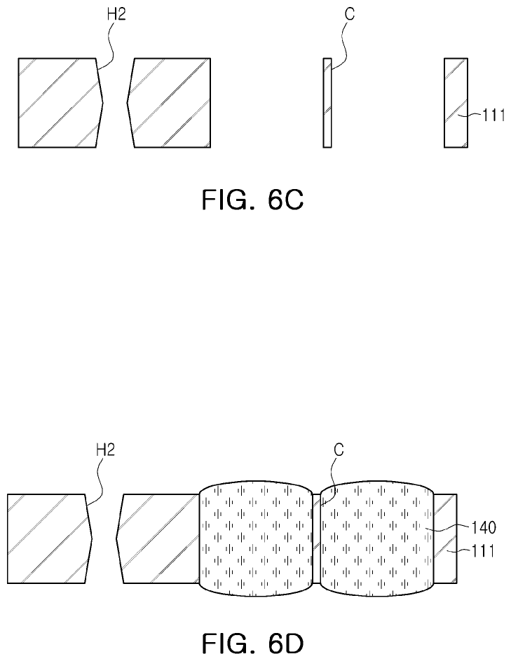

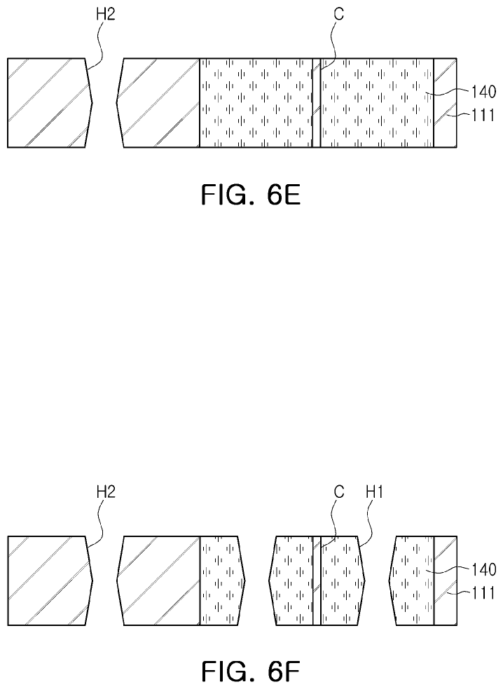

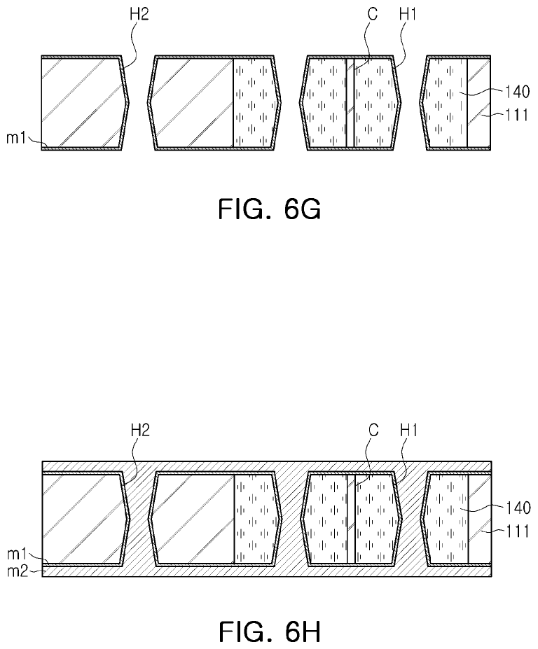

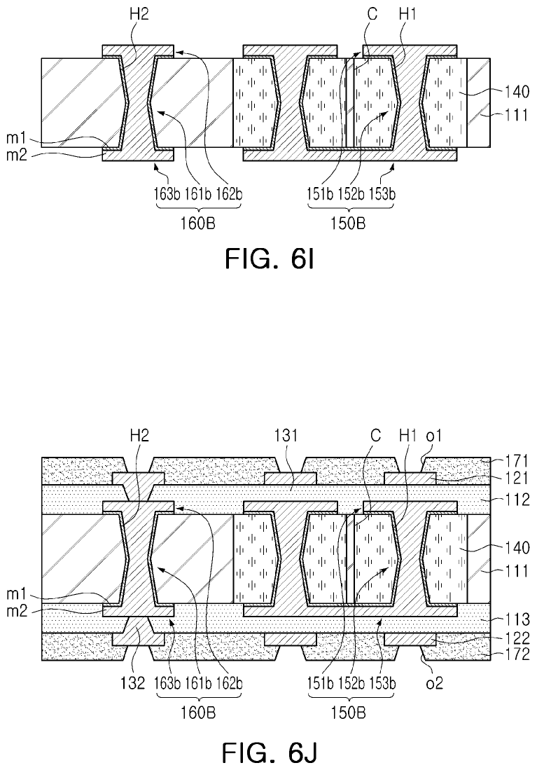

FIGS. 6A to 6J are cross-sectional views schematically illustrating an example embodiment of manufacturing the printed circuit board of FIG. 5.

Referring to FIG. 6A, a substrate 111 may be prepared. The substrate 111 may include an organic core layer, a glass core layer, a metal core layer, a silicon core layer, or a ceramic core layer, and may include, more preferably, a glass core layer. When the substrate 111 includes a glass core layer, a glass plate or the like may be prepared.

Referring to FIG. 6B, a plurality of holes h1 and h2 may be formed in the substrate 111. The plurality of holes h1 and h2 may be used to form a through-portion C or a second through-hole H4, which will be described below. The plurality of holes h1 and h2 may be formed through laser processing or the like.

Referring to FIG. 6C, a through-portion C and a second through-hole H2 may be formed in the substrate 111. The through-portion C and the second through-hole H2 may be formed by expanding a plurality of holes h1 and h2 previously formed in the substrate 111. For example, the plurality of holes h1 and h2 may be expanded through chemical etching to form the through-portion C and the second through-hole H2. If necessary, a plurality of through-portions C may be formed.

Referring to FIG. 6D, a magnetic layer 140 may be formed in the through-portion C. For example, the magnetic material layer 140 may be formed by filling the through-portion C with a magnetic paste or a magnetic composition and hardening the through-portion C. When there are a plurality of through-portions C, the magnetic layer 140 may be formed in each of the through-portions C.

Referring to FIG. 6E, the magnetic layer 140 may be flattened. For example, a polishing process may be performed so that an upper surface and a lower surface of the magnetic layer 140 are substantially coplanar with an upper surface and a lower surface of the substrate 111, respectively. When there are a plurality of magnetic layers 140, the polishing process may be flattened in substantially the same manner.

Referring to FIG. 6F, a first through-hole H1 may be formed in the magnetic layer 140. The first through-hole H1 may be formed using a mechanical drill or the like. When there are a plurality of magnetic layers 140, a first through-hole H1 may be formed in each of the magnetic layers 140.

Referring to FIG. 6G, a first metal layer m1 may be formed on the substrate 111, the magnetic layer 140, and the first and second through-holes H1 and H2. For example, the first metal layer m1 may be formed by performing sputtering using titanium (Ti), copper (Cu), or the like, as a material. If necessary, electroless plating may be performed after sputtering. For example, the first metal layer m1 may also include chemical copper.

Referring to FIG. 6H, a second metal layer m2 may be formed by performing electroplating using copper Cu or the like, as a material. The second metal layer m2 may be formed through peel plating.

Referring to FIG. 6I, first and second through-vias 150B and 160B may be formed. For example, the first to fourth pattern layers 152b, 153b, 162b and 163b may be formed by patterning the first and second metal layers m1 and m2 through chemical etching. Accordingly, the first and second through-vias 150B and 160B described above may be formed.

Referring to FIG. 6J, through a build-up process, and the like, the first and second insulating layers 112 and 113, the first and second wiring layers 121 and 122, and the first and second via layers 131 and 132 may be formed as many layers as the required number of layers. Additionally, first and second resist layers 171 and 172 may be formed. Additionally, a plurality of first and second openings o1 and o2 may be formed in the first and second resist layers 171 and 172, respectively. Meanwhile, the first and second insulating layers 112 and 113 may be formed in a lamination process, and the like, the first and second wiring layers 121 and 122 and the first and second via layers 131 and 132 may be formed in a plating process after via hole processing, and the first and second resist layers 171 and 172 may be formed in a lamination process or a coating process of liquid materials. Additionally, the plurality of first and second openings o1 and o2 may be formed using a photolithography process or a laser drill, depending on the material of the first and second resist layers 171 and 172.

A printed circuit board 100B according to another example embodiment described above may be manufactured through a series of processes, and other descriptions may be substantially the same as those described for the printed circuit board 100A according to an example embodiment described above and the printed circuit board 100B according to another example embodiment, and thus, overlapping descriptions thereof will be omitted.

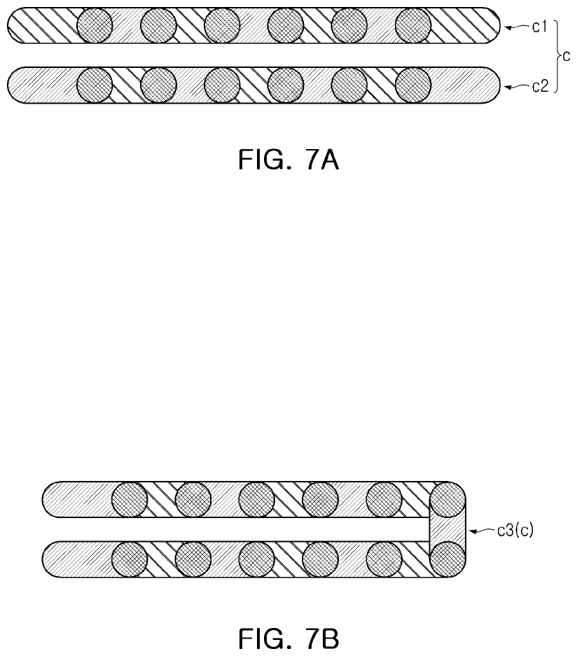

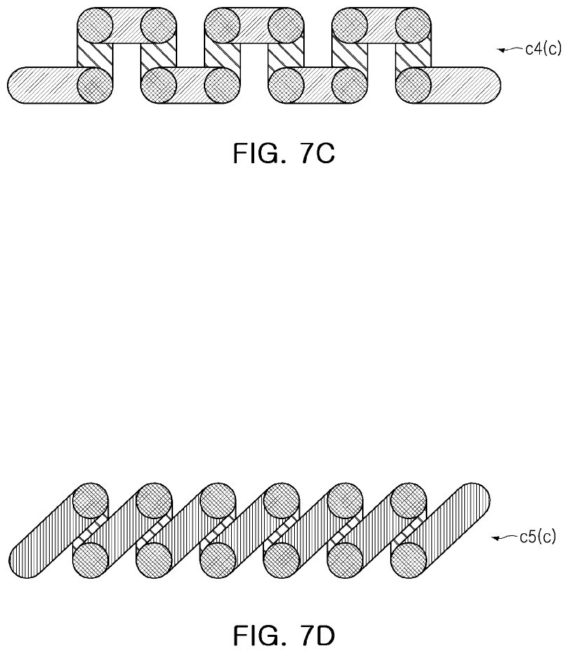

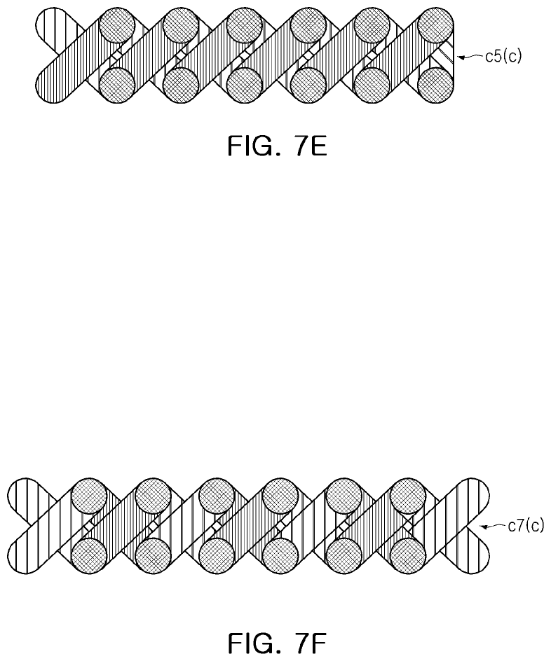

FIGS. 7A to 7F are plan views schematically illustrating various examples of a coil unit that may be applied to the printed circuit board of FIG. 3 and the printed circuit board of FIG. 5.

Referring to FIG. 7A, a coil unit c may include a plurality of coils c1 and c2 disposed in parallel and straight line. The plurality of coils c1 and c2 may be disposed to be spaced apart from each other. Another wiring may be disposed between the plurality of coils c1 and c2.

Referring to FIG. 7B, the coil unit c may include a coil c3 disposed in a straight line and then bent on the right side and disposed in a straight line again.

Referring to FIG. 7C, the coil unit c may include a coil c4 disposed to be repeatedly bent up and down.

Referring to FIG. 7D, the coil unit c may include a coil c5 repeatedly disposed in a shape inclined in one direction.

Referring to FIG. 7E, the coil unit c may include a coil c6 repeatedly disposed in an inclined form in one direction and then bent from the right and repeatedly disposed in an inclined form in an opposite direction.

Referring to FIG. 7F, the coil unit c may include a coil c7 repeatedly disposed in an X-shape.

For example, the coil unit c including various types of coils c1, c2, c3, c4, c5, c6 and c7 may be applied to the above-described printed circuit boards 100A and 100B. According to one aspect, a pattern shown in FIGS. 7A to 7F having a circular shape may correspond to a via structure disposed in the through-hole H1 in the above-described printed circuit boards 100A and 100B, and a pattern connected to adjacent two of the circular shapes in FIGS. 7A to 7F may correspond to the structure of either 153a or 153b (or a corresponding structure similar to either 153a or 153b, but disposed on the upper side) in the above-described printed circuit board 100A or 100B to connect adjacent via structures disposed in the adjacent through-holes H1 in the above-described printed circuit board 100A or 100B. However, the shape of the coil unit c is not limited to the example embodiments described above.

Other descriptions may be substantially the same as those described for the printed circuit board 100A according to the above-described example embodiment and the printed circuit board 100B according to another example embodiment, and thus, overlapping descriptions thereof will be omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of approximately filling, and may include, for example, a case in which some pores or voids exist. Additionally, the expression ‘surrounding’ may include not only a completely surrounding case, but also a partially surrounding case and an approximately surrounding case. Furthermore, exposing may include partially exposing as well as completely exposing, and exposure may refer to exposure from embedding a corresponding configuration. For example, exposing a pad by an opening may be exposing a pad from a resist layer, and a surface treatment layer or the like may be further disposed on the exposed pad.

In the present disclosure, being disposed in a through-portion or a through-hole may include a case in which an object is completely disposed in the through-portion or the through-hole, as well as a case in which the object partially protrudes upward or downward on a cross-section. For example, when the object is disposed in a through-portion or a through-hole on a plane, this may be determined in a broader meaning.

In the present disclosure, determination may be performed by including process errors, positional deviations, errors at the time of measurement, which may occur substantially in a manufacturing process. For example, being substantially vertical may include not only a case of being completely vertical, but also the case of being approximately vertical. Furthermore, being substantially coplanar may include not only a case of being completely coplanar, but also a case of being approximately coplanar.

In this disclosure, the same insulating material may include only a case of the completely same insulating material, but also the same type of insulating material. Accordingly, compositions of the insulating material are substantially the same, but specific composition ratios thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a lower side, a lower portion, and a lower surface are used to refer to a downward direction with respect to a cross-section of a drawing, and an upper side, an upper portion, and an upper surface are used to refer to an opposite direction thereof. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a substrate having a through-portion;
a magnetic layer at least partially disposed in the through-portion and having a first through-hole;
a first through-via layer disposed in the first through-hole;
a first pattern layer disposed on an upper surface of the magnetic layer and covering at least a portion of an upper end of the first through-via layer; and
a second pattern layer disposed on a lower surface of the magnetic layer and covering at least a portion of a lower end of the first through-via layer,
wherein the first through-via layer is in contact with a wall surface of the first through-hole,
at least a portion of the first pattern layer is in contact with the upper surface of the magnetic layer, and
at least a portion of the second pattern layer is in contact with the lower surface of the magnetic layer.

2. The printed circuit board according to claim 1, wherein the substrate has a second through-hole, and further comprises:
a second through-via layer disposed in the second through-hole;
a third pattern layer disposed on an upper surface of the substrate and covering at least a portion of an upper end of the second through-via layer; and
a fourth pattern layer disposed on a lower surface of the substrate and covering at least a portion of a lower end of the second through-via layer,
wherein the second through-via layer is in contact with a wall surface of the second through-hole,
at least a portion of the third pattern layer is in contact with the upper surface of the substrate, and
at least a portion of the fourth pattern layer is in contact with the lower surface of the substrate.

3. The printed circuit board according to claim 2, wherein the first through-via layer includes a first-first metal layer disposed on the wall surface of the first through-hole, a first-second metal layer disposed on the first-first metal layer, and a first filling material disposed in at least a portion of a space between the first-second metal layers, and
the second through-via layer includes a second-first metal layer disposed on the wall surface of the second through-hole, a second-second metal layer disposed on the second-first metal layer, and a second filling material disposed in at least a portion of a space between the second-second metal layers.

4. The printed circuit board according to claim 3, wherein the wall surfaces of the first and second through-holes are substantially perpendicular to at least one of the upper surface and the lower surface of one of the magnetic layer and the substrate, respectively.

5. The printed circuit board according to claim 3, wherein the first pattern layer includes the first-first metal layer disposed on the upper surface of the magnetic layer, the first-second metal layer disposed on the first-first metal layer, the first filling material disposed in at least the portion of the space between the first-second metal layers, and a first-third metal layer disposed on an upper surface of each of the first-second metal layer and the first filling material,
the second pattern layer includes the first-first metal layer disposed on the lower surface of the magnetic layer, the first-second metal layer disposed on the first-first metal layer, the first filling material disposed in at least the portion of the space between the first-second metal layers, and a first-fourth metal layer disposed on a lower surface of each of the first-second metal layer and the first filling material,
the third pattern layer includes the second-first metal layer disposed on the upper surface of the substrate, the second-second metal layer disposed on the second-first metal layer, the second filling material disposed in at least the portion of the space between the second-second metal layers, and a second-third metal layer disposed on an upper surface of each of the second-second metal layer and the second filling material, and
the fourth pattern layer includes the second-first metal layer disposed on the lower surface of the substrate, the second-second metal layer disposed on the second-first metal layer, the second filling material disposed in at least the portion of the space between the second-second metal layers, and a second-fourth metal layer disposed on a lower surface of each of the second-second metal layer and the second filling material.

6. The printed circuit board according to claim 2, wherein the first through-via layer includes a first-first metal layer disposed on the wall surface of the first through-hole, and a first-second metal layer disposed on the first-first metal layer and disposed in at least a portion of the first through-hole without a filling material, and
the second through-via layer includes a second-first metal layer disposed on the wall surface of the second through-hole, and a second-second metal layer disposed on the second-first metal layer and disposed in at least a portion of the second through-hole without a filling material.

7. The printed circuit board according to claim 6, wherein each of the wall surfaces of the first and second through-holes has a plurality of inclined surfaces inclined with respect to at least one of the upper surface and the lower surface of one of the magnetic layer and the substrate.

8. The printed circuit board according to claim 6, wherein the first pattern layer includes the first-first metal layer disposed on the upper surface of the magnetic layer, and the first-second metal layer disposed on an upper surface of the first-first metal layer,
the second pattern layer includes the first-first metal layer disposed on the lower surface of the magnetic layer, and the first-second metal layer disposed on a lower surface of the first-first metal layer,
the third pattern layer includes the second-first metal layer disposed on the upper surface of the substrate, and the second-second metal layer disposed on an upper surface of the second-first metal layer, and
the fourth pattern layer includes the second-first metal layer disposed on the lower surface of the substrate, and the second-second metal layer disposed on a lower surface of the second-first metal layer.

9. The printed circuit board according to claim 2, further comprising:
a first insulating layer disposed on an upper surface of each of the substrate and the magnetic layer, and covering at least a portion of each of the first and third pattern layers;
a second insulating layer disposed on a lower surface of each of the substrate and the magnetic layer, and covering at least a portion of each of the second and fourth pattern layers;
a first wiring layer disposed on an upper surface of the first insulating layer;
a second wiring layer disposed on a lower surface of the second insulating layer;
a first via layer penetrating through at least a portion of the first insulating layer, and connecting at least a portion of at least one of the first and third pattern layers with at least a portion of the first wiring layer; and
a second via layer penetrating through at least a portion of the second insulating layer, and connecting at least a portion of at least one of the second and fourth pattern layers with at least a portion of the second wiring layer.

10. The printed circuit board according to claim 9, further comprising:
a first resist layer disposed on the upper surface of the first insulating layer, and having a plurality of first openings respectively exposing at least a portion of the first wiring layer; and
a second resist layer disposed on the lower surface of the second insulating layer, and having a plurality of second openings respectively exposing at least a portion of the second wiring layer.

11. The printed circuit board according to claim 9, wherein the substrate includes the through-portion in plural form,
the magnetic layer is disposed in each of the plurality of through-portions,
each of the plurality of magnetic layers has the first through-hole,
the first through-via layer is disposed in each of the plurality of first through-holes,
the plurality of first through-via layers are connected to each other through at least one of the first and second pattern layers to form one or more coil units disposed in a form of surrounding at least a portion of each of the plurality of magnetic layers.

12. The printed circuit board according to claim 1, wherein the magnetic layer is in contact with a wall surface of the through-portion.

13. The printed circuit board according to claim 1, wherein the upper surface of the magnetic layer is substantially coplanar with an upper surface of the substrate, and
the lower surface of the magnetic layer is substantially coplanar with a lower surface of the substrate.

14. The printed circuit board according to claim 1, wherein the substrate includes an organic core layer, a glass core layer, a metal core layer, a silicon core layer, or a ceramic core layer.

15. A printed circuit board, comprising:
a substrate having a through-portion;
a magnetic layer at least partially disposed in the through-portion and having a through-hole;
a first metal layer disposed on a wall surface of the through-hole, and extending onto an upper surface and a lower surface of the magnetic layer; and
a second metal layer disposed on the first metal layer and disposed in at least a portion of the through-hole,
wherein the first metal layer is in contact with each of the wall surface of the through-hole, the upper surface of the magnetic layer, and the lower surface of the magnetic layer.

16. The printed circuit board according to claim 15, further comprising:
a filling material disposed between the second metal layers, disposed in at least another portion of the through-hole, and partially protruding from the upper surface and the lower surface of the magnetic layer, respectively;
a third metal layer disposed on an upper surface of each of the second metal layer and the filling material; and
a fourth metal layer disposed on a lower surface of each of the second metal layer and the filling material.

17. The printed circuit board according to claim 15, wherein the second metal layer is disposed in at least a portion of the through-hole without a filling material, and
at least a portion of each of an upper surface and a lower surface of the second metal layer is in contact with an insulating material.

18. The printed circuit board according to claim 15, further comprising:
a magnetic composite inductor (MCI) including the magnetic layer, the through-hole, and the first and second metal layers.

19. A printed circuit board, comprising:
a substrate having a first through-portion and a second through-portion;
a first magnetic layer at least partially disposed in the first through-portion and having a first through-hole;
a second magnetic layer at least partially disposed in the second through-portion and having a second through-hole;
a first through-via layer disposed in the first through-hole;
a second through-via layer disposed in the second through-hole;
a first pattern layer disposed on an upper surface of the first magnetic layer and covering at least a portion of an upper end of the first through-via layer;
a second pattern layer disposed on lower surfaces of the first and second magnetic layers and covering at least a portion of each lower end of the first and second through-via layers; and
a third pattern layer disposed on an upper surface of the second magnetic layer and covering at least a portion of an upper end of the second through-via layer,
wherein a portion of the substrate is disposed between the first magnetic layer and the second magnetic layer to separate the first magnetic layer and the second magnetic layer from each other.

20. The printed circuit board according to claim 19, further comprising:
a first insulating layer disposed on the substrate and the first and second magnetic layers, and covering at least a portion of each of the first and third pattern layers;
a second insulating layer disposed below the substrate and the first and second magnetic layer, and covering at least a portion of the second pattern layers;
a first wiring layer disposed on an upper surface of the first insulating layer;
a second wiring layer disposed on a lower surface of the second insulating layer; and
a first via layer penetrating through at least a portion of the first insulating layer, and connecting at least a portion of at least one of the first and third pattern layers with at least a portion of the first wiring layer.
